(19) United States
(12) Patent Application Publication
(10) Pub. No.: US 2026/0285031 A1
(43) Pub. Date: Sep. 24, 2026

(54) ELECTRONIC DEVICE, INKJET PRINTING APPARATUS, AND METHOD FOR MANUFACTURING DISPLAY PANEL USING THE INKJET PRINTING APPARATUS

(71) Applicant: Samsung Display Co., Ltd., Yongin-Si (KR)

(72) Inventors: YU KONTA, Yongin-si (KR); Cheong-Wan MIN, Yongin-si (KR)

(21) Appl. No.: 19/379,894

(22) Filed: Nov. 5, 2025

(30) Foreign Application Priority Data
Mar. 20, 2025 (KR) 10-2025-0035982

(51) Int. Cl. B41J 2/045; B41J 3/407; H10K 71/10; H10K 71/13

(52) U.S. Cl. CPC B41J 2/04505; B41J 3/407; H10K 71/135; H10K 71/191

(57) ABSTRACT

Provided is an inkjet printing apparatus. The inkjet printing apparatus includes a stage on which a substrate is configured to be disposed, the substrate including a first mark disposed in a print area and a second mark spaced apart from the first mark and disposed in the print area, a head unit disposed on the stage, a first camera unit disposed on a side surface of the head unit, and a second camera unit disposed on a side surface of the head unit and spaced apart from the first camera unit in a first direction DR1. The first camera unit is configured to capture the first mark and the second mark, and the second camera unit is configured to capture the first mark.

### CROSS-REFERENCE TO RELATED APPLICATIONS

This U.S. non-provisional patent application claims priority under 35 U.S.C. § 119 to Korean Patent Application No. 10-2025-0035982, filed on Mar. 20, 2025, the entire contents of which are hereby incorporated by reference.

### BACKGROUND

The present disclosure herein relates to an electronic device, an inkjet printing apparatus, and a method for manufacturing a display panel using the same.

In general, an organic light-emitting diode display (OLED), which exhibits excellent luminance characteristics and viewing angle characteristics and does not require a separate light source unlike a liquid crystal display, is attracting attention as a next-generation flat panel display. Since an organic light-emitting diode display does not require a separate light source, it may be manufactured to be lightweight and thin. In addition, the organic light-emitting diode display has characteristics such as low power consumption, high luminance, and high response speed.

The organic light-emitting diode display includes a plurality of light-emitting elements each of which includes an anode, an organic light-emitting layer, and a cathode. A hole and an electron are respectively injected from the anode and the cathode into the organic light-emitting layer, an exciton is generated, and light is emitted as the exciton transitions to a ground state.

When a light-emitting element is manufactured, the organic light-emitting layer is manufactured using an inkjet printing apparatus. An organic material (or ink) for forming the organic light-emitting layer is discharged from the inkjet printing apparatus onto a substrate, so that the organic light-emitting layer may be formed.

When an organic light-emitting diode display is manufactured, a high-resolution and precise patterning process is required. As the pixel size of the organic light-emitting diode display having high resolution becomes smaller, the inkjet printing apparatus must discharge a smaller amount of ink to a designated position. If the discharge position of the ink is not precisely controlled due to vibrations or the like generated in the apparatus during the printing process of the inkjet printing apparatus, a defective organic light-emitting layer may be produced. Accordingly, there is a need for the development of an inkjet printing apparatus capable of precisely controlling the discharge position of ink.

### SUMMARY

The present disclosure provides an inkjet printing apparatus capable of reducing a defect rate of an organic light-emitting layer. More specifically, an object of the inventive concept is to provide an inkjet printing apparatus capable of precisely controlling an ink discharge position by reducing a positional error of a position recognition camera caused by vibrations or the like during the process of the inkjet printing apparatus.

The present disclosure also provides a method for manufacturing a display panel capable of reducing a defect rate of an organic light-emitting layer. More specifically, an object of the inventive concept is to provide a method for manufacturing a display panel capable of precisely controlling an ink discharge position by reducing a positional error of a position recognition camera caused by vibrations or the like during the process of the inkjet printing apparatus.

The present disclosure also provides an electronic device capable of reducing a defect rate of an organic light-emitting layer.

An embodiment of the inventive concept provides an inkjet printing apparatus including: a stage on which a substrate is configured to be disposed, the substrate including a first mark disposed in a print area and a second mark spaced apart from the first mark and disposed in the print area; a head unit disposed on the stage; a first camera unit disposed on a side surface of the head unit; and a second camera unit disposed on a side surface of the head unit and spaced apart from the first camera unit in a first direction, wherein the first camera unit is configured to capture the first mark and the second mark, and the second camera unit is configured to capture the first mark.

In an embodiment, the first camera unit captures the first mark in a (1-1)-th mode, the first camera unit captures the second mark in a (1-2)-th mode, and the second camera unit captures the first mark in a second mode.

In an embodiment, the (1-1)-th mode may be repeated at least twice.

In an embodiment, the (1-2)-th mode may be repeated at least twice.

In an embodiment, the second mode may be repeated at least twice.

In an embodiment, a plurality of first variations are generated in the (1-1)-th mode, and a plurality of second variations are generated in the second mode.

In an embodiment, differences in each of the first variations may be corrected to place the first camera unit on the second mark in a plan view.

In an embodiment, differences in each of the second variations may be corrected to place the second camera unit on the first mark in a plan view.

In an embodiment, the head unit may include: a housing disposed on the substrate; a plurality of print heads disposed inside the housing; a plurality of nozzles respectively disposed on bottom surfaces of the print heads; and an ink supply unit configured to supply ink to the print heads.

In an embodiment, the inkjet printing apparatus may include a guide line on which the first camera unit and the second camera unit are disposed.

In an embodiment of the inventive concept, a method for manufacturing a display panel includes: placing, on a stage, a substrate in which a print area is defined, the print area including a first mark and a second mark spaced apart from the first mark; capturing the first mark using a first camera; capturing the second mark using the first camera; capturing the first mark using a second camera and discharging ink onto the substrate.

In an embodiment, capturing the first mark using the first camera may be repeated at least twice.

In an embodiment, capturing the second mark spaced apart from the first mark using the first camera may be repeated at least twice.

In an embodiment, capturing the first mark using the second camera may be repeated at least twice.

In an embodiment, the method for manufacturing the display panel may further include measuring a plurality of first variations based on the captured first mark using the first camera; and measuring a plurality of second variations based on the captured first mark using the second camera.

In an embodiment, the method for manufacturing the display panel may further include compensating differences in the first variations and placing the first camera unit on the second mark in a plan view.

In an embodiment, the method for manufacturing the display panel may further include compensating differences in the second variations and placing the second camera unit on the first mark in a plan view.

In an embodiment, the head unit may include: a housing placed on the substrate; a plurality of print heads disposed inside the housing; a plurality of nozzles disposed on bottom surfaces of the print heads, respectively; and an ink supply unit configured to supply the ink to the print heads.

In an embodiment of the inventive concept, an electronic device includes: a display device configured to display an image; and a processor configured to process an image signal and provide the processed image signal to the display device, wherein the display device includes a pixel manufactured by: placing a substrate on a stage, the substrate including a print area in which a first mark and a second mark spaced apart from the first mark is disposed; ; capturing the first mark using a first camera; capturing a second mark using the first camera; capturing the first mark using a second camera; and discharging ink onto the substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a FIG. 1 is a block diagram of an electronic device according to an embodiment of the inventive concept;

FIG. 2 is schematic views of the electronic device according to an embodiment of the inventive concept;

FIG. 3 is a diagram illustrating a method for forming an organic light-emitting layer using an inkjet printing apparatus;

FIG. 4 is a view illustrating an example of a cross-section of a pixel shown in FIG. 3;

FIG. 5 is a perspective view of an inkjet printing apparatus according to an embodiment of the inventive concept;

FIG. 6 is a schematic perspective view illustrating a head unit according to an embodiment of the inventive concept;

FIGS. 7, 8, 9 and 10 are plan views of an inkjet printing apparatus according to an embodiment of the inventive concept; and

FIG. 11 is a flowchart illustrating a method for manufacturing a display panel according to an embodiment of the inventive concept.

### DETAILED DESCRIPTION

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like numbers refer to like elements throughout. Also, in the figures, the thickness, ratio, and dimensions of components are exaggerated for clarity of illustration. The term “and/or” includes any and all combinations of one or more of the associated listed items.

Although the terms “first,” “second,” etc. may be used herein to describe various elements, these elements should not be limited by these terms. The terms are used solely for the purpose of distinguishing one component, part, area, layer, or portion from another component, part, area, layer, or portion. For example, without departing from the scope of the inventive concept, a first component, first part, first area, first layer, or first portion may be referred to as a second component, second part, second area, second layer, or second portion, and similarly, a second component, second part, second area, second layer, or second portion may be referred to as a first component, first part, first area, first layer, or first portion. The singular forms include the plural forms as well unless the context clearly indicates otherwise.

Also, “under”, “below”, “above’, “upper”, and the like are used for explaining relation association of components illustrated in the drawings. These terms are used as a spatially relative concept and are described based on the directions indicated in the drawings.

It will be understood that the term “include” or “comprise”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, the inventive concept will be explained in detail with reference to the accompanying drawings.

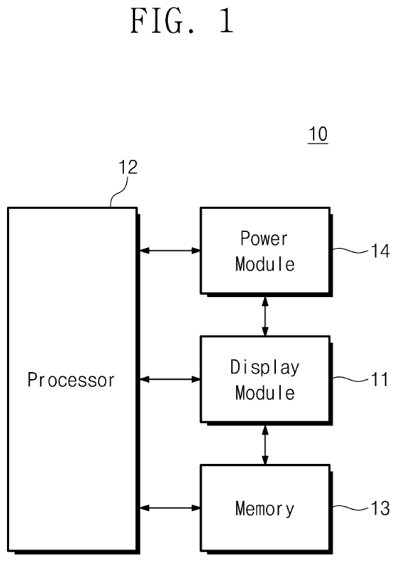

FIG. 1 is a block diagram of an electronic device according to an embodiment of the inventive concept.

Referring to FIG. 1, the electronic device 10 may include a display module 11, a processor 12, a memory 13, and a power module 14.

The processor 12 may include at least one of a central processing unit CPU, an application processor AP, a graphic processing unit GPU, a communication processor CP, an image signal processor ISP, or a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal to output image information through a display screen.

The power module 14 may include a power supply module, such as a power adapter or a battery device, and a power conversion module that converts the power supplied by the power supply module to generate the power required for the operation of the electronic device 10.

At least one of the components of the above-described electronic device 10 may be included in the display device according to the above-described embodiments. In addition, a part of the individual modules functionally included in a single module may be included in the display device, and the other part may be provided separately from the display device. For example, the display device may include the display module 11, and the processor 12, the memory 15, and the power module 14 may be provided in the type of another component within the electronic device 10 rather than in the display device.

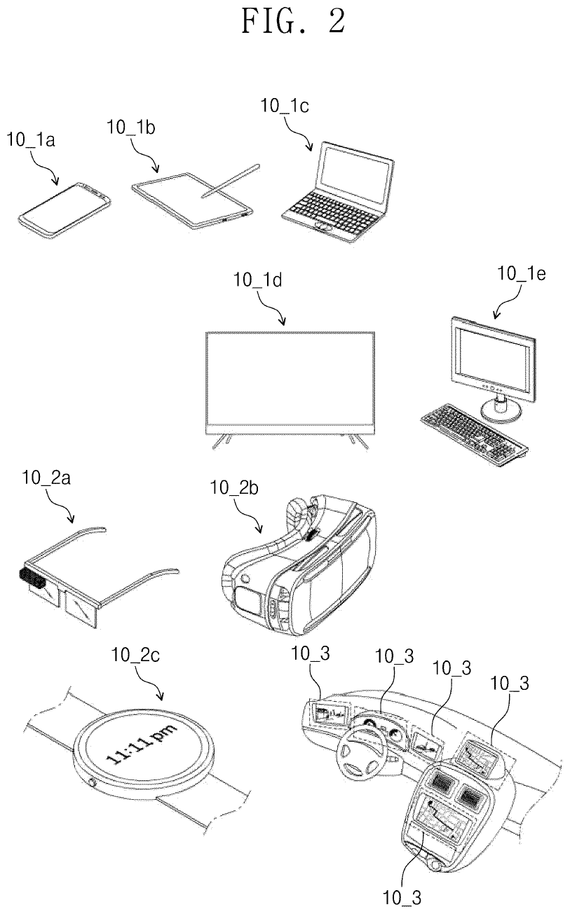

FIG. 2 is schematic views of the electronic device according to an embodiment of the inventive concept.

Referring to FIG. 2, various electronic devices to which the display device according to the embodiments is applied may include image display electronic devices such as a smartphone 10_1a, a tablet PC 10_1b, a laptop 10_1c, a TV 10_1d, and a desktop monitor 10_1e; wearable electronic devices including a display module, such as smart glasses 10_2a, a head-mounted display 10_2b, and a smart watch 10_2c; and vehicle electronic devices including a display module arranged in a dash board, for example, a CID (Center Information Display), a center console, and a room mirror display, etc.

The electronic device may include a display device that displays an image, and a processor that processes an image signal and provides the processed image signal to the display device. The display device may include a display panel that is manufactured by a display panel manufacturing method, which will be described later.

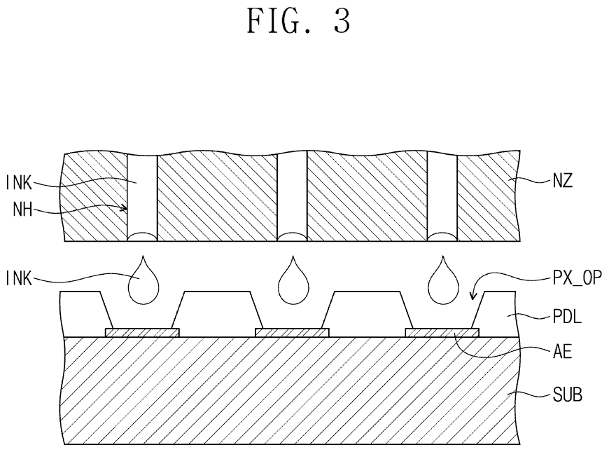

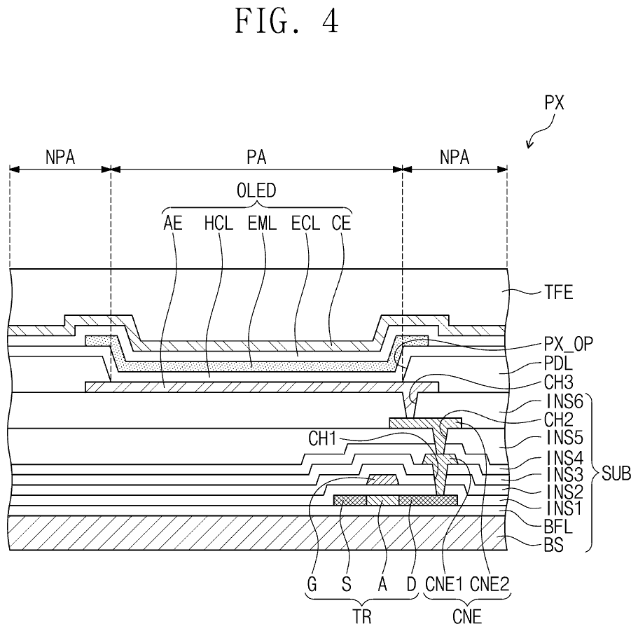

FIG. 3 is a diagram illustrating a method of forming an organic light-emitting layer using an inkjet printing apparatus. FIG. 4 is a view illustrating an example of a cross-section of a pixel shown in FIG. 3.

For convenience of explanation, FIG. 3 illustratively shows a cross-sectional view of a nozzle part NZ in which three nozzle holes NH are defined.

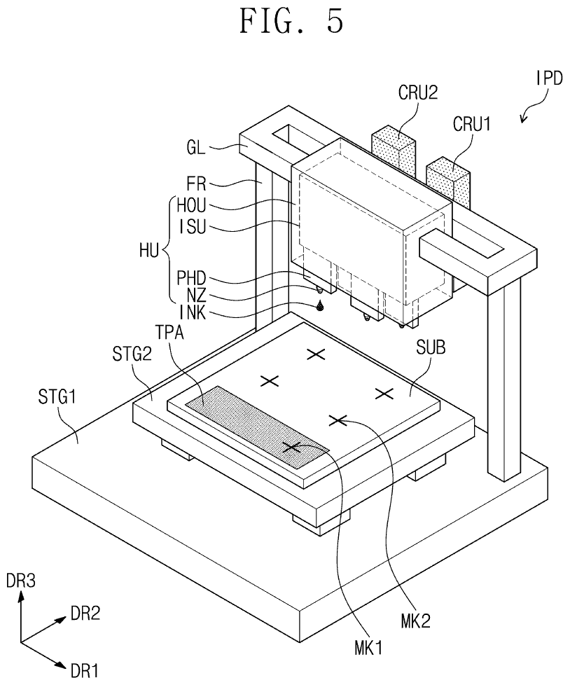

Referring to FIGS. 3 and 4, an inkjet printing apparatus IPA (see FIG. 5A) may be used to provide a light-emitting layer EML (see FIG. 4). A pixel PX may include a transistor TR and a light-emitting element OLED connected to the transistor TR. Although one pixel PX is shown as an example, a plurality of pixels PX may be disposed on a base layer BS.

The light emitting element OLED may include a first electrode AE, a second electrode CE, a hole control layer HCL, an electron control layer ECL, and an light emitting layer EML. The first electrode AE may be an anode electrode and the second electrode CE may be a cathode electrode.

The transistor TR and the light-emitting element OLED may be disposed on the base layer BS. A planar area of the base layer BS may include an emission part PA and a non-emission part NPA around the emission part PA. The light-emitting element OLED may be disposed on the emission part PA.

A buffer layer BFL may be disposed on the base layer BS, and the buffer layer BFL may be an inorganic layer.

Semiconductor patterns S, A, and D may be disposed on the buffer layer BFL. The semiconductor patterns S, A, and D may include polysilicon. However, the semiconductor patterns S, A, and D are not limited thereto and may also include amorphous silicon or a metal oxide.

The semiconductor patterns S, A, and D may be doped with an N-type dopant or a P-type dopant. The semiconductor pattern may include a high-doped region and a low-doped region. A conductivity of a highly doped region may be greater than that of a low-doped region, and the highly doped region may substantially serve as source and drain electrodes of the transistor TR. The low-doped region may effectively correspond to an active (or channel) of the transistor.

A source S, an active A, and a drain D of the transistor TR may be provided from the semiconductor patterns S, A, and D. A first insulating layer INS1 may be disposed on the semiconductor patterns S, A, and D. A gate electrode G of the transistor TR may be disposed on the first insulating layer INS1. A second insulating layer INS2 may be disposed on the gate electrode G. A third insulating layer INS3 may be disposed on the second insulating layer INS2.

A connection electrode CNE may be disposed between the transistor TR and the light-emitting element OLED to connect the transistor TR and the light-emitting element OLED. The connection electrode CNE may include a first connection electrode CNE1 and a second connection electrode CNE2.

The first connection electrode CNE1 may be disposed on the third insulating layer INS3 and may be connected to the drain D through a first contact hole CH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in the fifth insulating layer INS5 and the fourth insulating layer INS4. A sixth insulating layer INS6 may be disposed on the second connection electrode CNE2. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through the third contact hole CH3 defined in the sixth insulating layer INS6. A pixel defining layer PDL, which exposes a predetermined portion of the first electrode AE, may be disposed on the first electrode AE and the sixth insulating layer INS6. An opening portion PX_OP for exposing a predetermined portion of the first electrode AE may be defined in the pixel defining PDL.

The hole control layer HCL may be disposed on the first electrode AE and the pixel defining layer PDL. A hole control layer HCL may be commonly disposed on the emission part PA and the non-emission part NPA. The hole control layer HCL may include a hole transport layer and a hole injection layer.

The emission layer EML may be disposed on the hole control layer HCL. The emission layer EML may be disposed on an area corresponding to the opening OP. The emission layer EML may include organic and/or inorganic materials. The emission layer EML may emit one of red light, green light, and blue light.

The electron control layer ECL may be disposed on the emission layer EML and the hole control layer HCL. The electron control layer ECL may be commonly disposed on the emission part PA and the non-emission part NPA. The electron control layer ECL may include an electron transport layer and an electron injection layer.

The second electrode CE may be disposed on the electronic control layer ECL. The second electrode CE may be commonly disposed on the pixels PX.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer between the at least two inorganic layers. The inorganic layers may protect the pixel PX from moisture and oxygen. The organic layer may protect the pixel PX from foreign substances such as dust particles.

A first voltage may be applied to the first electrode AE through the transistor TR, and a second voltage having a lower level than the first voltage may be applied to the second electrode CE. A hole and an electron injected into the light emitting layer EML are coupled to each other to form an exciton, and while the exciton is transited to a ground state, the light emitting element OLED may emit light.

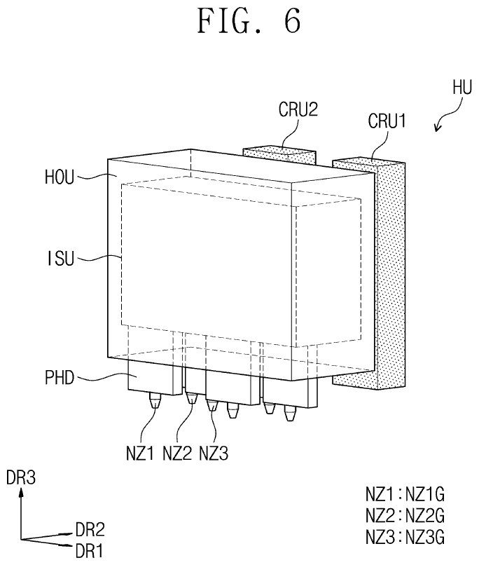

FIG. 5 is a perspective view of an inkjet printing apparatus according to an embodiment of the inventive concept. FIG. 6 is a schematic perspective view illustrating a head unit according to an embodiment of the inventive concept. In FIG. 6, for convenience of explanation, a guide lines GL is omitted.

Referring to FIGS. 5 and 6, an inkjet printing apparatus IPD may include a first stage STG1, a second stage STG2, a head unit HU, a guide line GL, a first camera unit CRU1, and a second camera unit CRU2.

The second stage STG2 may be disposed on the first stage STG1. Suction holes (not shown) may be defined in the second stage STG2. A substrate SUB may be adsorbed and fixed on the second stage STG2 through the suction holes of the second stage STG2.

The substrate SUB may be disposed on the second stage STG2. The substrate SUB may include a print area TPA. Ink INK may be applied to the print area TPA. It may be confirmed whether the ink INK is applied to a target application area through the ink INK applied to the print area TPA. Whether the ink INK is applied to a desired position or not may be confirmed through the second camera unit CRU2.

The substrate SUB may include a first mark MK1 and a second mark MK2. The first mark MK1 may be disposed in the print area TPA in a plan view. The second mark MK2 may be spaced apart from the first mark MK1 in a second direction DR2 intersecting a first direction DR1.

The head unit HU may be disposed on the substrate SUB. The head unit HU may include a housing HOU disposed on the substrate SUB, a plurality of print heads PHD disposed inside the housing HOU, a plurality of nozzles NZ1, NZ2, and NZ3, and an ink supply unit ISU. The housing HOU may protect the ink supply unit ISU, the nozzles NZ, and the print heads PHD.

The nozzles NZ1, NZ2, and NZ3 may be disposed on bottom surfaces of each print heads PHD. The nozzles NZ1, NZ2, and NZ3 may include a plurality of first nozzles NZ1 arranged in the first direction DR1. The first nozzles NZ1 may be defined as a first nozzle group NZ1G. The nozzles NZ1, NZ2, and NZ3 may include a plurality of second nozzles NZ2 arranged in the first direction DR1. The second nozzles NZ2 may be defined as a second nozzle group NZ2G. The nozzles NZ1, NZ2, and NZ3 may include a plurality of third nozzles NZ3 arranged in the first direction DR1. The third nozzles NZ3 may be defined as a third nozzle group NZ3G.

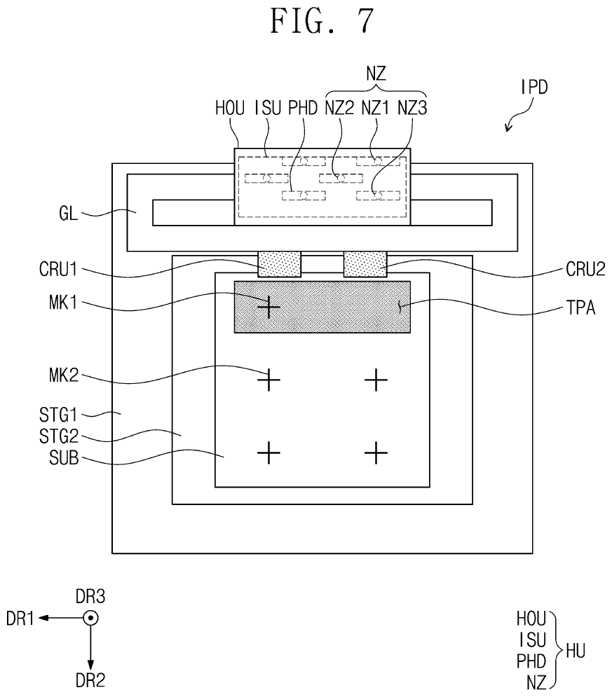

The first nozzle group NZ1G, the second nozzle group NZ2G, and the third nozzle group NZ3G may be arranged in the second direction DR2 intersecting the first direction DR1. That is, the first nozzle group NZ1G, the second nozzle group NZ2G, and the third nozzle group NZ3G may be connected to the ink supply unit ISU and categorized as separate groups. In FIGS. 6 and 7, for example, the nozzles NZ1, NZ2, and NZ3 of the respective nozzle groups NZ1G, NZ2G, and NZ3G are illustrated, but the number of the nozzles NZ1, NZ2, and NZ3 is not limited, as long as the nozzles NZ1, NZ2, and NZ3 may be defined as groups.

The first nozzles NZ1 and the third nozzles NZ3 may be arranged in the same columns in the second direction DR2. The first nozzles NZ1 and the third nozzles NZ3 may overlap in the second direction DR2. The second nozzles NZ2 may be disposed in columns between the columns where the first nozzles NZ1 are disposed. That is, the second nozzles NZ2 may not overlap the first nozzles NZ1 and the third nozzles NZ3 in the second direction DR2. In a view from the second direction DR2, the second nozzles NZ2 may be disposed between the first nozzles NZ1 and the third nozzles NZ3.

The ink supply unit ISU may be connected to the print heads PHD. The ink supply unit ISU may supply ink INK (see FIG. 2) to the print heads PHD. The ink INK may be discharged from nozzles NZ1, NZ2, and NZ3 through the ink supply unit ISU.

The first camera unit CRU1 may be disposed on a side surface of the head unit HU. The first camera unit CRU1 may be disposed on the guide line GL. The first camera unit CRU1 may capture alignment of the substrate SUB to measure the alignment state. During the process, the substrate SUB or the first camera unit CRU1 may be slightly displaced from its original position due to vibrations or the like. As a result, the position of the ink INK applied to the substrate may be out of position degraded, thus display quality of the display device may be deteriorated.

The first camera unit CRU1 may capture a first mark MK1 and a second mark MK2 of the substrate SUB to calculate a positional error. Based on this information, the position of the print heads PHD or the substrate SUB may be adjusted to compensate for the error. When real-time alignment correction is performed, patterning precision may be maintained and yield may be improved.

The second camera unit CRU2 may be spaced apart from the first camera unit CRU1 in the first direction DR1. The second camera unit CRU2 may be disposed on a side surface of the head unit HU and may be disposed on the guide line GL. The second camera unit CRU2 may capture whether ink INK applied to the substrate SUB is correctly applied to a target position. Due to vibrations or the like during the process, the second camera unit CRU2 may be slightly displaced from its original position. As a result, an error may occur in the positional information of the ink INK captured by the second camera unit CRU2.

The second camera unit CRU2 may capture the first mark MK1. Based on this, the second camera unit CRU2 may calculate a displacement error in its position. Based on the information, a discharge position of the ink INK from nozzles NZ may be corrected. The discharge position of the ink INK may be corrected to allow the ink INK to be applied to a desired position.

A frame FR may connect the first stage STG1 to the head unit HU.

FIGS. 7 to 10 are plan views of an inkjet printing apparatus according to an embodiment of the inventive concept.

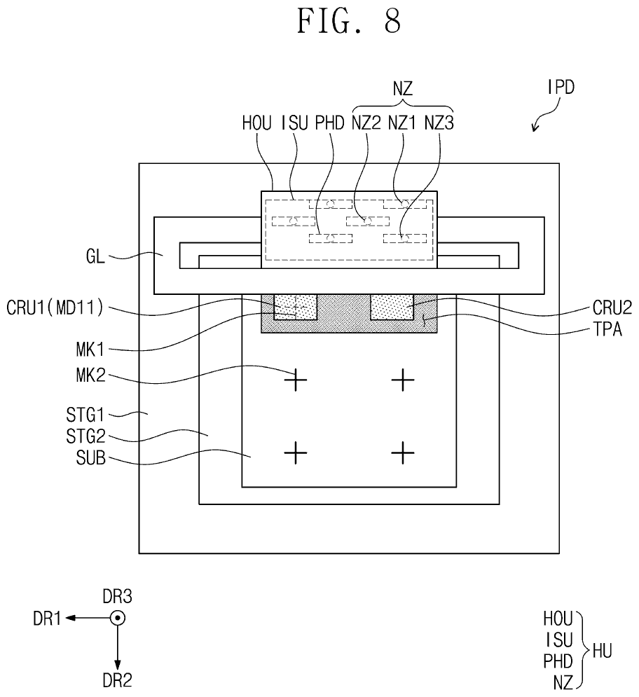

Referring to FIGS. 7 and 8, an operation in which the first camera unit CRU1 captures the first mark MK1 may be defined as a (1-1)-th mode MD11. The (1-1)-th mode MD11 may be repeated at least twice. The first camera unit CRU1 may capture a reference point to assist alignment of the substrate SUB.

The first camera unit CRU1 may capture the first mark MK1 in a first row to set an initial position. When a positional error of the first camera unit CRU1 occurs due to vibrations or the like during the process, the first camera unit CRU1 may capture the first mark MK1 again to calculate a deviation from the initial position. Such positional error correction may reduce or eliminate a phenomenon in which the substrate SUB is misaligned from the initial state.

That is, the (1-1)-th mode MD11 may generate a plurality of first variations captured by the first camera unit CRU1 with respect to the first mark MK1. During the process, the first camera unit CRU1 may capture the first mark MK1 multiple times. A positional value of the first mark MK1 captured by the first camera unit CRU1 during the process may differ from an initial positional value of the first mark MK1 captured first by the first camera unit CRU1 due to vibrations or the like. The positional error of the first camera unit CRU1 due to vibrations or the like during the process may be corrected, whereby misalignment of the substrate SUB may be reduced or eliminated.

The first camera unit CRU1 may be positioned on the second mark MK2 in a plan view after compensating differences in each of the first variation amounts. Differences in each of the first variations are corrected to place the first camera unit on the second mark in a planar view. When the first camera unit CRU1 captures the second mark MK2 to align the substrate SUB, the positional error calculated in the (1-1)-th mode MD11 (see FIG. 8) may be corrected and the second mark MK2 may be captured. Accordingly, misalignment of the substrate SUB may be reduced or eliminated.

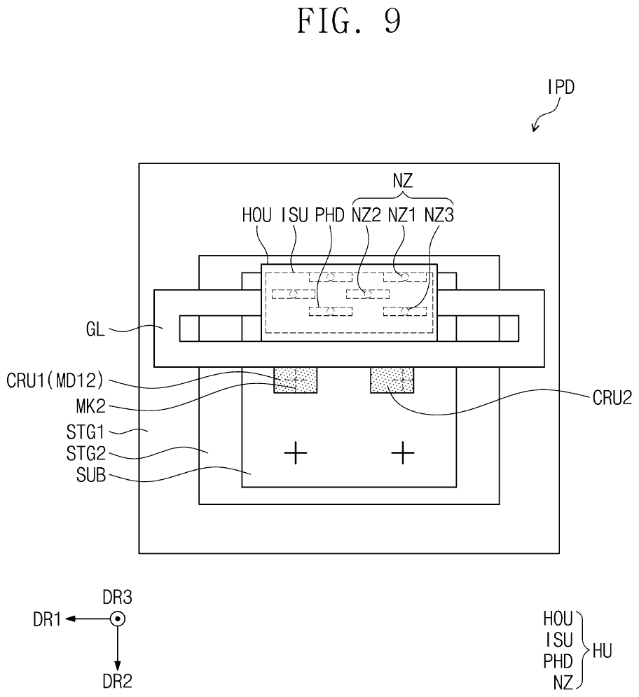

Referring to FIGS. 7 and 9, an operation in which the first camera unit CRU1 captures the first mark MK1 in a second row may be defined as a (1-2)-th mode MD12. The (1-2)-th mode MD12 may be repeated at least twice.

The first camera unit CRU1 may capture the second mark MK2 in the second row to align the substrate SUB. In this case, the first camera unit CRU1 may capture the second mark MK2 by correcting the positional error in the first mark MK1 in the (1-1)-th mode MD11 (see FIG. 8). The first camera unit CRU1 may align the substrate SUB based on a result of capturing the second mark MK2.

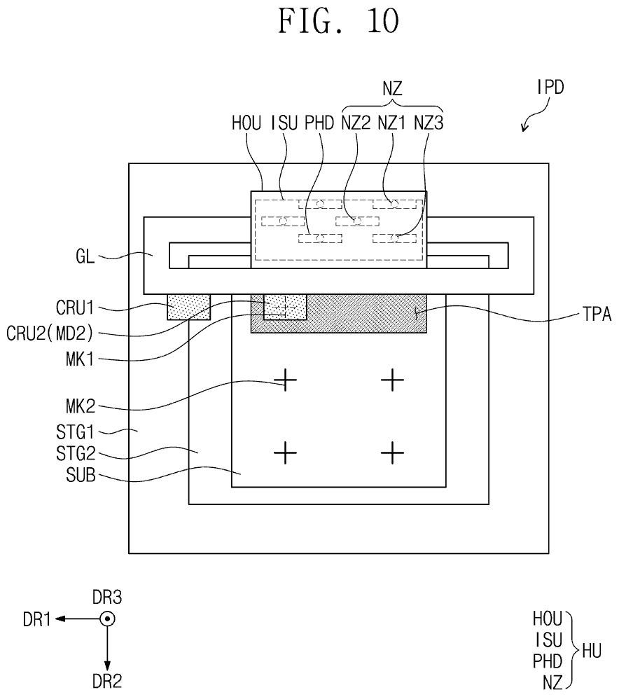

Referring to FIGS. 7 and 10, an operation in which the second camera unit CRU2 captures the first mark MK1 may be defined as a second mode MD2. The second mode MD2 may be repeated at least twice. The second camera unit CRU2 may provide a reference value for adjusting an application position of the ink INK (see FIG. 5) such that the ink INK may be applied to a desired position on the substrate SUB. The second camera unit CRU2 may capture the first mark MK1 and calculate a landing position value of the ink INK within the print area TPA.

The second camera unit CRU2 may capture the first mark MK1 to set an initial position and, when a positional error of the second camera unit CRU2 occurs due to vibrations or the like during the process, the second camera unit CRU2 may capture the first mark MK1 again to calculate a deviation from the initial position. Such positional error correction may reduce or eliminate a phenomenon in which the ink INK is applied to a position offset from a target application position.

That is, the second mode MD2 may generate a plurality of second variations captured by the second camera unit CRU2 with respect to the first mark MK1. During the process, the second camera unit CRU2 may capture the first mark MK1 multiple times. A positional value of the first mark MK1 captured by the second camera unit CRU2 during the process may differ from an initial positional value of the first mark MK1 captured first by the second camera unit CRU2 due to vibrations or the like. Since a positional error of the second camera unit CRU2 due to vibrations or the like during the process is corrected, a phenomenon in which the ink INK is applied to a position offset from the target application position may be reduced or eliminated.

For example, the second camera unit CRU2 may be positioned on the first mark MK1 in a plan view after compensating each of the second variation amount. Differences in each of the second variations are corrected to place the second camera unit on the first mark in a planar view. When the second camera unit CRU2 captures the first mark MK1 to determine an application position of the ink INK, the first mark MK1 may be captured in consideration of the positional error calculated in the second mode MD2. Accordingly, it is possible to reduce or eliminate a phenomenon in which the ink INK is applied to a position offset from the target application position.

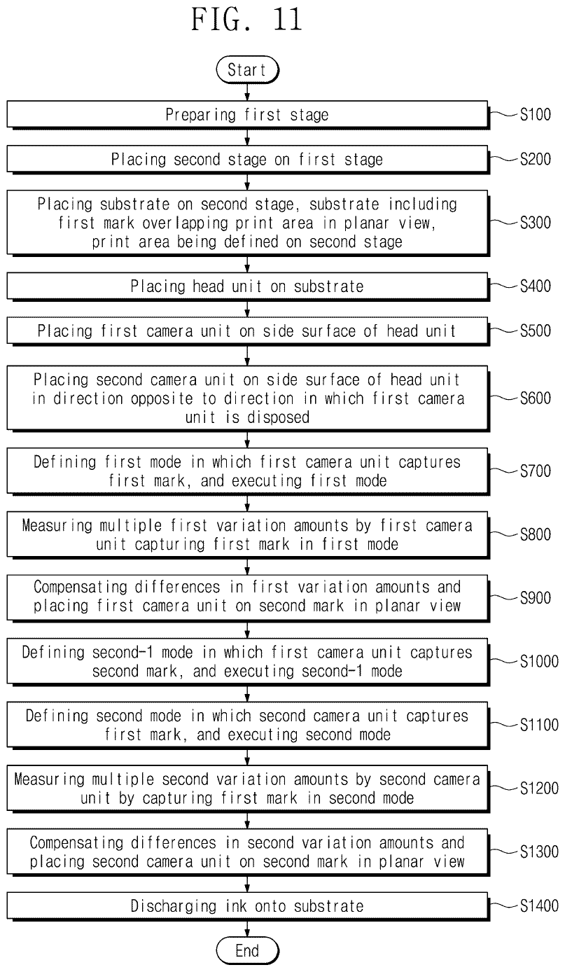

FIG. 11 is a flowchart illustrating a method for manufacturing a display panel according to an embodiment of the inventive concept.

Referring to FIGS. 7 and 11, a method for manufacturing a display panel may include a step S100 of preparing a first stage STG1. The method may include a step S200 of placing a second stage STG2 on the first stage STG1. The method may include a step S300 of placing, on the second stage STG2, a substrate SUB in which a print area TPA is defined and which includes a first mark MK1 overlapping the print area TPA in a plan view. The method may include a step S400 of placing a head unit HU on the substrate SUB.

The method may include a step S500 of placing a first camera unit CRU1 on a side of the head unit HU. The first camera unit CRU1 may move in a first direction DR1 along a guide line GL and may be disposed on the guide line GL. The first camera unit CRU1 may provide a reference point for aligning the substrate SUB.

The method may include a step S600 of placing a second camera unit CRU2, which is spaced apart from the first camera unit CRU1 in the first direction DR1, on a side of the head unit HU. The second camera unit CRU2 may move in the first direction DR1 along the guide line GL and may be disposed on the guide line GL. The second camera unit CRU2 may provide a reference point for a discharge position of ink INK (see FIG. 5).

Referring to FIGS. 8 and 11, the method may include a step S700 of defining the first mode in which the first camera unit CRU1 captures the first mark MK1 in a first row as a (1-1)-th mode MD11 and executing the (1-1)-th mode MD11. In the (1-1)-th mode MD11, the first camera unit CRU1 may set the position where the first mark MK1 is captured as a reference point. The (1-1)-th mode MD11 may be repeated multiple times during the process. When the position of the first camera unit CRU1 is changed due to vibrations or the like during the process, the first camera unit CRU1 may calculate a positional error by comparing the initially captured reference position of the first mark MK1 with the current captured position. This positional error may be corrected to adjust the position of the first camera unit CRU1.

The method may include a step S800 of measuring a plurality of first variations in which the first camera unit CRU1 captures the first mark MK1 in the (1-1)-th mode MD11. The first variations may be compared to the initial reference position of the first mark MK1, and the position of the first camera unit CRU1 may be corrected based on each of the first variations. The method may include a step S900 of compensating differences in the first variations to place the first camera unit CRU1 on the second mark MK2 in a plan view. The first camera unit CRU1 may be placed on the second mark MK2 in a second row and may capture the second mark MK2.

Referring to FIGS. 9 and 11, the method for manufacturing the display panel may include a step S1000 of defining second-1 mode in which the first camera unit CRU1 captures the second mark MK2 and executing the (1-2)-th mode. When the alignment of the substrate SUB is misaligned based on the position where the second mark MK2 is captured, the first camera unit CRU1 may assist in aligning the substrate SUB. In this case, the position of the first camera unit CRU1 may be corrected by an amount of the first variations to reduce or eliminate misalignment of the first camera unit CRU1 caused by vibrations or the like during the alignment process.

Referring to FIGS. 10 and 11, the method may include a step S1100 of defining the second mode in which the second camera unit CRU2 captures the first mark MK1 and executing the second mode MD2. In the second mode MD2, the second camera unit CRU2 may set a position where the first mark MK1 is captured as a reference point. The second mode MD2 may be repeated multiple times during the process. When the position of the second camera unit CRU2 is changed due to vibrations or the like during the process, the second camera unit CRU2 may calculate a positional error by comparing the initially captured reference position of the first mark MK1 with the current captured position. This positional error may be corrected to adjust the position of the second camera unit CRU2.

The method may include a step S1200 of measuring a plurality of second variation amount in which the second camera unit CRU2 captures the first mark MK1 in the second mode MD2. The second variations may be compared to the initial reference position of the first mark MK1, and the position of the second camera unit CRU2 may be corrected based on each of the second variations. The method may include a step S1300 of compensating differences in the second variation amounts to place the second camera unit CRU2 on the second mark MK2 in a plan view. The second camera unit CRU2 may be positioned on the second mark MK2 and may capture the second mark MK2.

When the ink INK (see FIG. 5) is misaligned from a target ink application position based on the captured position of the first mark MK1, the second camera unit CRU2 may assist in adjusting the application position of the ink INK. In this case, the position of the second camera unit CRU2 may be corrected by the amount of the second variation amounts to reduce or eliminate misalignment, which is caused by vibrations or the like during the ink INK application alignment process. The method for manufacturing the display panel may include a step S1400 of discharging ink INK onto the substrate SUB.

As described above, the position value of the first mark captured by the first camera unit CRU1 during the process may differ from the initial position value of the first mark captured by the first camera unit due to vibrations or the like during the process. By compensating for the positional error of the first camera unit caused by vibrations or the like during the process, misalignment of the substrate may be reduced or eliminated.

The position value of the first mark captured by the second camera unit during the process may differ from the initial position value of the first mark captured by the second camera unit due to vibrations or the like during the process. By compensating for the positional error of the second camera unit caused by vibrations or the like during the process, the phenomenon in which ink is applied to the position deviated from the target application position may be reduced or eliminated.

Although the embodiments of the inventive concept have been described, it is understood that the inventive concept should not be limited to these embodiments but various changes and modifications can be made by one ordinary skilled in the art within the spirit and scope of the inventive concept as hereinafter claimed.

What is claimed is:

1. An inkjet printing apparatus comprising:
a stage on which a substrate is configured to be disposed, the substrate including a first mark disposed in a print area and a second mark spaced apart from the first mark and disposed in the print area;
a head unit disposed on the stage;
a first camera unit disposed on a side surface of the head unit; and
a second camera unit disposed on a side surface of the head unit and spaced apart from the first camera unit in a first direction,
wherein the first camera unit is configured to capture the first mark and the second mark, and the second camera unit is configured to capture the first mark.

2. The inkjet printing apparatus according to claim 1, wherein the first camera unit captures the first mark in a (1-1)-th mode, the first camera unit captures the second mark in a (1-2)-th mode, and the second camera unit captures the first mark in a second mode.

3. The inkjet printing apparatus according to claim 2, wherein the (1-1)-th mode is repeated at least twice.

4. The inkjet printing apparatus according to claim 2, wherein the (1-2)-th mode is repeated at least twice.

5. The inkjet printing apparatus according to claim 2, wherein the second mode is repeated at least twice.

6. The inkjet printing apparatus according to claim 2, wherein a plurality of first variations are generated in the (1-1)-th mode, and
wherein a plurality of second variations are generated in the second mode.

7. The inkjet printing apparatus according to claim 6, wherein differences in each of the first variations are corrected to place the first camera unit on the second mark in a plan view.

8. The inkjet printing apparatus according to claim 6, wherein differences in each of the second variations are corrected to place the second camera unit on the first mark in a plan view.

9. The inkjet printing apparatus according to claim 1, wherein the head unit comprises:
a housing disposed on the substrate;
a plurality of print heads disposed inside the housing;
a plurality of nozzles respectively disposed on bottom surfaces of the print heads; and
an ink supply unit configured to supply ink to the print heads.

10. The inkjet printing apparatus according to claim 1, further comprising a guide line on which the first camera unit and the second camera unit are disposed.

11. A method for manufacturing a display panel, comprising:
placing, on a stage, a substrate in which a print area is defined, the print area including a first mark and a second mark spaced apart from the first mark;
capturing the first mark using a first camera;
capturing the second mark using the first camera;
capturing the first mark using a second camera; and
discharging ink onto the substrate.

12. The method according to claim 11, wherein the capturing the first mark using the first camera is repeated at least twice.

13. The method according to claim 11, wherein capturing the second mark spaced apart from the first mark using the first camera is repeated at least twice.

14. The method according to claim 11, wherein capturing the first mark using the second camera is repeated at least twice.

15. The method according to claim 11, further comprising:
measuring a plurality of first variations based on the captured first mark using the first camera; and
measuring a plurality of second variations based on the captured first mark using the second camera.

16. The method according to claim 15, further comprising compensating differences in the first variations and placing the first camera unit on the second mark in a plan view.

17. The method according to claim 15, further comprising compensating differences in the second variations and placing the second camera unit on the first mark in a plan view.

18. The method according to claim 11, wherein the head unit comprises:
a housing placed on the substrate;
a plurality of print heads disposed inside the housing;
a plurality of nozzles disposed on bottom surfaces of the print heads, respectively; and
an ink supply unit configured to supply the ink to the print heads.

19. An electronic device comprising:
a display device configured to display an image; and
a processor configured to process an image signal and provide the processed image signal to the display device,
wherein the display device comprises a pixel manufactured by:
placing a substrate on a stage, the substrate including a print area in which a first mark and a second mark spaced apart from the first mark is disposed;
capturing the first mark using a first camera;
capturing the second mark using the first camera ;
capturing the first mark using a second camera; and
discharging ink onto the substrate.
